(19) United States
(12) Patent Application Publication
(10) Pub. No.: US 2024/0099035 A1
(43) Pub. Date: Mar. 21, 2024

(54) DOUBLE-SIDED EMBEDDED MEMORY ARRAY

(71) Applicant: INTERNATIONAL BUSINESS MACHINES CORPORATION, Armonk, NY (US)

(72) Inventors: Wu-Chang Tsai, Albany, NY (US); Ailian Zhao, Slingerlands, NY (US); Ashim Dutta, Clifton Park, NY (US); Chih-Chao Yang, Glenmont, NY (US)

(21) Appl. No.: 17/946,147

(22) Filed: Sep. 16, 2022

(51) Int. Cl. H01L 27/105; H01L 23/48

(52) U.S. Cl. CPC H01L 27/1052; H01L 23/481

(57) ABSTRACT

A semiconductor structure is presented including a first memory array and a second memory array directly connected to the first memory array by nanosheet stacks and backside contacts. The first and second memory arrays collectively define a double-sided memory array on a complementary metal oxide semiconductor (CMOS) wafer. The nanosheet stacks separate the first memory array from the second memory array so that two different types of memory devices are integrated together into a single CMOS chip.

### BACKGROUND

The present invention relates generally to semiconductor devices, and more specifically, to a double-sided embedded memory array.

Semiconductor devices are used in a variety of electronic applications, such as personal computers, cell phones, digital cameras, and other electronic equipment. Semiconductor devices are usually fabricated by sequentially depositing insulating or dielectric layers, conductive layers, and semiconductive layers of material over a semiconductor substrate, and patterning the various material layers using lithography to form circuit components and elements thereon.

The semiconductor industry has experienced rapid growth due to improvements in the integration density of a variety of electronic components (e.g., transistors, diodes, resistors, capacitors, etc.). For the most part, this improvement in integration density has come from shrinking the semiconductor process node. With the increased demands for miniaturization, higher speed, greater bandwidth, lower power consumption, and lower latency, chip layout has become more complicated and difficult to achieve in the production of semiconductor dies.

### SUMMARY

In accordance with an embodiment, a semiconductor structure is provided. The semiconductor structure includes a first memory array and a second memory array directly connected to the first memory array by nanosheet stacks and backside contacts.

In accordance with another embodiment, a semiconductor structure is provided. The semiconductor structure includes a first memory′ array and a second memory array integrated with the first memory array by at least a plurality of nanosheet stacks to define a single complementary metal oxide semiconductor (CMOS) chip.

In accordance with yet another embodiment, a method for forming a semiconductor structure is provided. The method includes forming a first set of S/D contacts within a silicon on insulator (SOI) layer of a wafer, forming nanosheet stacks over portions of the SOI layer, constructing a first memory array, flipping the wafer, removing the portions of the SOI layer, constructing a second memory array, and re-flipping the wafer so that the second memory array is integrated with the first memory array by at least the nanosheet stacks to define a single complementary metal oxide semiconductor (CMOS) chip.

It should be noted that the exemplary embodiments are described with reference to different subject-matters. In particular, some embodiments are described with reference to method type claims whereas other embodiments have been described with reference to apparatus type claims. However, a person skilled in the art will gather from the above and the following description that, unless otherwise notified, in addition to any combination of features belonging to one type of subject-matter, also any combination between features relating to different subject-matters, in particular, between features of the method type claims, and features of the apparatus type claims, is considered as to be described within this document.

These and other features and advantages will become apparent from the following detailed description of illustrative embodiments thereof, which is to be read in connection with the accompanying drawings.

### BRIEF DESCRIPTION OF THE DRAWINGS

The invention will provide details in the following description of preferred embodiments with reference to the following figures wherein:

FIG. 1 is a cross-sectional view of a semiconductor structure where contact formation takes place within the wafer, in accordance with an embodiment of the present invention;

FIG. 2 is a cross-sectional view of the semiconductor structure of FIG. 1 where nanosheet stacks, gate contacts, and source/drain (sir)) contacts are formed, in accordance with an embodiment of the present invention;

FIG. 3 is a cross-sectional view of the semiconductor structure of FIG. 2 where middle-of-line (MOL), back-end-of-line (BEOL), and a first memory array are formed, in accordance with an embodiment of the present invention;

FIG. 4 is a cross-sectional view of the semiconductor structure of FIG. 3 where the lifer is flipped, in accordance with an embodiment of the present invention;

FIG. 5 is a cross-sectional view of the semiconductor structure of FIG. 4 where silicon (Si) and oxide removal is performed, in accordance with an embodiment of the present invention:

FIG. 6 is a cross-sectional view of the semiconductor structure of FIG. 5 where a dielectric is deposited over the contacts and the nanosheet stacks, in accordance with an embodiment of the present invention;

FIG. 7 is a cross-sectional view of the semiconductor structure of FIG. 6 MOL, BEOL, and a second memory array are formed, in accordance with an embodiment of the present invention; and

FIG. 8 is a cross-sectional view of the semiconductor structure of FIG. 7 where the wafer is flipped such that the first memory array is on the top and the second memory array is on the bottom, in accordance with an embodiment of the present invention.

Throughout the drawings, same or similar reference numerals represent the same or similar elements.

### DETAILED DESCRIPTION

Embodiments in accordance with the present invention provide methods and devices for constructing a double-sided embedded memory array. There is a need to place memory as close to transistors as possible to minimize RC delay for last level cache applications to replace static random access memory (SRAM). As a result, memory device size/pitch should shrink down accordingly. However, there are challenges for size and pitch reduction of memory devices embedded in typical complementary metal oxide semiconductor (CMOS) back-end-of-line (BEOL) in order to further increase packing density of memory. For example, high performance magnetoresistive random access memory (MRAM) integration is challenged to embed at the 14 nm and below nodes. In view thereof, the exemplary embodiments of the present invention provide an alternative way to increase embedded memory array density without reducing device size and pitch, that is, by allowing two different types of memory devices to be integrated together into a single CMOS chip. It is noted that conventional memory devices are embedded in a single-sided BEOL structure, whereas the exemplary embodiments of the present invention introduce a backside memory array embedded and connected to a front side memory array, through nanosheet stacks and backside contacts.

In particular, the exemplary embodiments of the present invention introduce a structure of forming an embedded memory device where the structure is a wafer-level double-sided memory array on CMOS wafers. The memory arrays at both sides can be connected through nanosheets and back side contacts, e.g., through silicon vias (TSV), The memory arrays at both sides can be different types of memory devices. In this structure, the memory density is increased, without pitch reduction, which will provide more manufacturability. Further, the exemplary embodiments of the present invention introduce a method of forming embedded memory devices where, after a typical front side memory array process, a temporary carrier is used to carry and flip the wafer to fabricate the back side memory array. The back side embedded memory array is fabricated by conventional BEOL interconnect processes. However, the back side contacts are fabricated first before front side front-end-of-line (FEOL) and can be used as alignment marks for the beginning of the back side process.

Examples of semiconductor materials that can be used in forming such nanosheet structures include silicon (Si), germanium (Ge), silicon germanium alloys (SiGe), silicon carbide (SiC), silicon germanium carbide (SiGeC), III-V compound semiconductors and/or II-VI compound semiconductors. III-V compound semiconductors are materials that include at least one element from Group III of the Periodic Table of Elements and at least one element from Group V of the Periodic Table of Elements. II-VI compound semiconductors are materials that include at least one element from Group II of the Periodic Table of Elements and at least one element from Group VI of the Periodic Table of Elements.

It is to be understood that the present invention will be described in terms of a given illustrative architecture; however, other architectures, structures, substrate materials and process features and steps/blocks can be varied within the scope of the present invention. It should be noted that certain features cannot be shown in all figures for the sake of clarity. This is not intended to be interpreted as a limitation of any particular embodiment, or illustration, or scope of the claims.

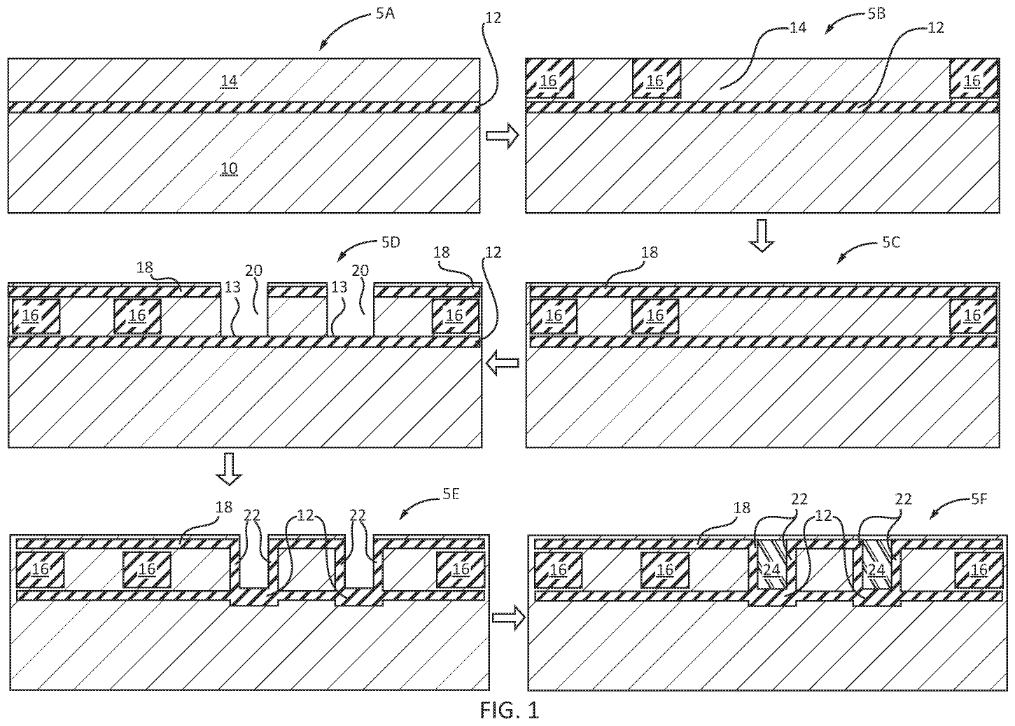

FIG. 1 is a cross-sectional view of a semiconductor structure where contact formation takes place within the wafer, in accordance with an embodiment of the present invention,

In various example embodiments, in structure 5A, a dielectric layer 12 is formed over a substrate 10. A silicon on insulator (SOT) layer 14 is formed over the dielectric layer 12.

In structure 5B, shallow trench isolation (STI) regions 16 are formed within the SOI layer 14. The ST1 regions 16 are formed such that an area of the SOI layer 14 is devoid of any of the STI regions 16. This is the area where CA contacts will be formed as described below.

In structure 5C, an oxide layer 18 is deposited over the SOI layer 14 and the STI regions 16.

In structure SD, etching takes place to create openings 20. The openings 20 extend to a top surface 13 of the dielectric layer 12. The openings 20 are configured to accommodate contact formation described below. The openings 20 are formed in the area devoid of any of the STI regions 16.

In structure 5E, dielectric liners 22 are formed within the openings 20 such that the dielectric liners 22 directly contact sidewalls of the SOI layer 14 and directly contact sidewalls of the oxide layer 18.

In structure 5F, contacts 24 are formed between the dielectric liners 22. The contacts 24 extend to a top surface of the oxide layer 18. The contacts 24 can be referred to as CA contacts. CA contacts are S/D contacts.

In one or more embodiments, the substrate 10 can be a semiconductor or an insulator with an active surface semiconductor layer. The substrate 10 can be crystalline, semi-crystalline, microcrystalline, or amorphous. The substrate 10 can be essentially (e.g., except for contaminants) a single element (e.g., silicon), primarily (e.g., with doping) of a single element, for example, silicon (Si) or germanium (Ge), or the substrate 10 can include a compound, for example, Al₂O₃, SiO₂, GaAs, SiC, or SiGe. The substrate 10 can also have multiple material layers, for example, a semiconductor-on-insulator substrate (SeOI), a silicon-on-insulator substrate (SOI), germanium-on-insulator substrate GeOI), or silicon-germanium-on-insulator substrate (SGOI). The substrate 10 can also have other layers forming the substrate 10, including high-k oxides and/or nitrides. In one or more embodiments, the substrate 10 can be a silicon wafer. In an embodiment, the substrate 10 is a single crystal silicon wafer.

Regarding various dielectrics or dielectric layers (such as the dielectric layer 12) discussed herein, the dielectrics can include, but are not limited to. SiN, SiOCN, SiOC, SiBCN, SO₂, or ultra-low-k (ULK) materials, such as, for example, porous silicates, carbon doped oxides, silicon dioxides, silicon nitrides, silicon oxynitrides, carbon-doped silicon oxide(SiCOH) and porous variants thereof, silsesquioxanes, siloxanes, or other dielectric materials having, for example, a dielectric constant in the range of about 2 to about 10.

In some embodiments, the dielectrics can be conformally deposited using atomic layer deposition (ALD) or, chemical vapor deposition (CVD). Variations of CVD processes suitable for forming the dielectrics include, but are not limited to, Atmospheric Pressure CVI) (APCVD), Low Pressure CVD (LPCVD) and Plasma Enhanced CVD (PECVD), Metal-Organic CVI) (MOCVD) and combinations thereof can also be employed.

The SOI layer 14 is fabricated using techniques that are well known to those skilled in the art. For example, the SOI layer 14 can be fabricated using a thermal bonding process, or alternatively the SOI layer 14 may be fabricated by an ion implantation process that is referred to in the art as separation by ion implantation of oxygen (SIMOX). When a thermal bonding process is employed in fabricating the 501 layer 14, an optional thinning step may be utilized to thin the top Si-containing layer into an ultra-thin regime.

The etching can include a dry etching process such as, for example, wet etch, reactive ion etching, plasma etching, ion etching or laser ablation. The etching can further include a wet chemical etching process in which one or more chemical etchants are used to remove portions of the blanket layers that are not protected by the patterned photoresist.

The dry and wet etching processes can have etching parameters that can be tuned, such as etchants used, etching temperature, etching solution concentration, etching pressure, source power, RE bias voltage, RF bias power, etchant flow rate, and other suitable parameters. Dry etching processes can include a biased plasma etching process that uses a chlorine-based chemistry. Other dry etchant gasses can include Tetrafluoromethane (CF₄), nitrogen trifluoride (NF₃), sulffir hexafluoride (SF₆), and helium (He), and Chlorine trifluoride (CIF₃) Dry etching can also be performed anisotropically using such mechanisms as DRIE (deep reactive-ion etching). Chemical vapor etching can be used as a selective etching method, and the etching gas can include hydrogen chloride (HCl), Tetrafluoromethane (CF₄), and gas mixture with hydrogen (H₂). Chemical vapor etching can be performed by CVD with suitable pressure and temperature.

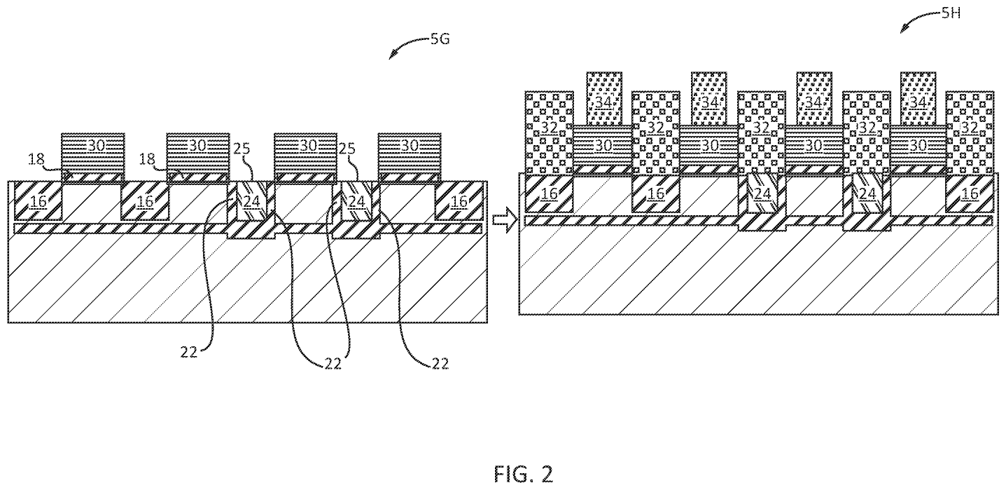

FIG. 2 is a cross-sectional view of the semiconductor structure of FIG. 1 where nanosheet stacks, gate contacts, and source/drain (S/D) contacts are formed, in accordance with an embodiment of the present invention.

In various example embodiments, in structure 5G, nanosheet stacks 30 are formed and patterning takes place. The nanosheet stacks 30 are formed over sections of the SOI layer 14. The nanosheets stacks 30 directly contact portions of the oxide layer 18. A top surface 25 of the contacts 24 remain exposed after patterning, Additionally, top surfaces of the dielectric liners 22 remain exposed after patterning.

In various example embodiments, in structure 5H, S/D) regions 32 are formed over the STI regions 16 and over the contacts 24. The S/D regions 32 directly contact sidewalls of the nanosheet stacks 30, The S/D regions 32 extend above a top surface of the nanosheet stacks 30. Gate contacts 34 are formed over and in direct contact with the nanosheet stacks 30. The gate contacts 34 and the nanosheet stacks 30 are horizontally offset from the contacts 24. The contacts 24 only directly contact a bottom surface of select SiD contacts.

The nanosheet stacks 30 each include alternating layers of a first semiconductor material (or layer) and a second semiconductor material (or laver), The first semiconductor material can be, e.g., silicon germanium (Site) and the second semiconductor material can be, e.g., silicon (Si).

Referring to, e.g, the nanosheet stacks 30, the first semiconductor material can be the first layer in a stack of sheets of alternating materials. The nanosheet stacks 30 thus includes first semiconductor materials (or layers) and second semiconductor materials (or layers). Although it is specifically contemplated that the first semiconductor materials can be formed from silicon germanium and that the second semiconductor materials can be formed from silicon, it should be understood that any appropriate materials can be used instead, as long as the two semiconductor materials have etch selectivity with respect to one another. As used herein, the term “selective” in reference to a material removal process denotes that the rate of material removal for a first material is greater than the rate of removal for at least another material of the structure to which the material removal process is being applied. The alternating semiconductor materials can be deposited by any appropriate mechanism. It is specifically contemplated that the first and second semiconductor materials can be epitaxially grown from one another, but alternate deposition processes, such as chemical vapor deposition (CND), physical vapor deposition (FM), atomic layer deposition (ALD), or gas cluster ion beam (GCiB) deposition, are also contemplated.

S/D regions 32 can be of the same or different materials for pFET and nFET devices, and can be either in-situ doped with appropriate polarity dopants (B for pFET and P for nFET devices) or doped by ion implantation.

The terms “epitaxial growth” and “epitaxial deposition” refer to the growth of a semiconductor material on a deposition surface of a semiconductor material, in which the semiconductor material being grown has substantially the same crystalline characteristics as the semiconductor material of the deposition surface. The term “epitaxial material” denotes a material that is formed using epitaxial growth. In some embodiments, when the chemical reactants are controlled and the system parameters set correctly, the depositing atoms arrive at the deposition surface with sufficient energy to move around on the surface and orient themselves to the crystal arrangement of the atoms of the deposition surface. Thus, in some examples, an epitaxial film deposited on a {100} crystal surface will take on a {100} orientation.

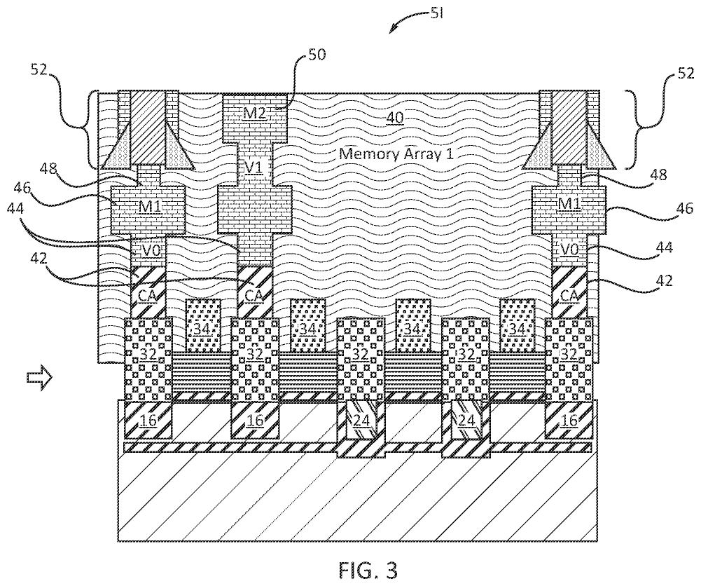

FIG. 3 is a cross-sectional view of the semiconductor structure of FIG. 2 where middle-of-line (MOIL), back-end-of-line (BEOL), and a first memory array are formed, in accordance with an embodiment of the present invention.

In various example embodiments, in structure 51, middle-of-line (MOL), back-end-of-line (BEOL), and a first memory array are formed. A dielectric layer 40 is first deposited. Then, for example, on the left-hand side, a CA contact 42 is formed over the S/D region 32, a via (VO) 44 is formed over the CA contact 42, an M1 layer 46 is formed over the via 44, and a via (V1) 48 is formed over the M1 layer 46. All these components are positioned within the dielectric layer 40. In one instance, an M2 layer 50 is formed over the via 48 and in another instance a magnetic tunnel junction (MTJ) structure 52 is formed over another via 48. Moreover, on the right-hand side, a CA contact 42 is formed over the S/D region 32, a via (VO) 44 is formed over the CA contact 42, an M1 layer 46 is formed over the via 44, and a via (V1) 48 is formed over the M1 layer 46. Also, an MTJ structure 52 is formed over the via 48. All these components are positioned within the dielectric layer 40. All these components collectively define the first memory array.

Non-limiting examples of suitable conductive materials for the CA contacts 42 include a silicide liner such as Ti, Ni, NiPt, etc., an adhesion metal liner, such as TiN, TaN, and conductive metal fill, such as Al, W, Co, Ru, etc. The conductive material can further include dopants that are incorporated during or after deposition. The conductive metal can be deposited by a suitable deposition process, for example, CVD, PECVD, PVD, plating, thermal or e-beam evaporation, and sputtering.

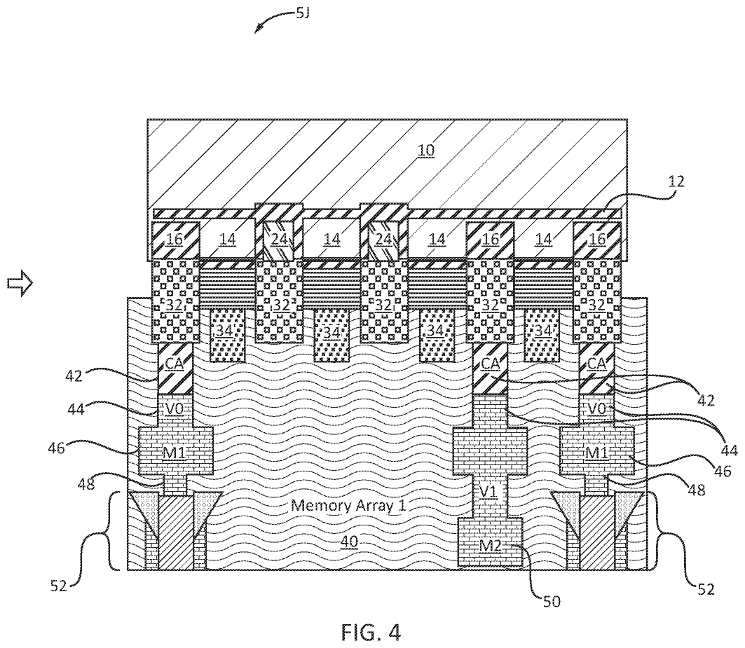

FIG. 4 is a cross-sectional view of the semiconductor structure of FIG. 3 where the wafer is flipped, in accordance with an embodiment of the present invention.

In various example embodiments, in structure 5J, the wafer is flipped such that the substrate 10 is positioned on top.

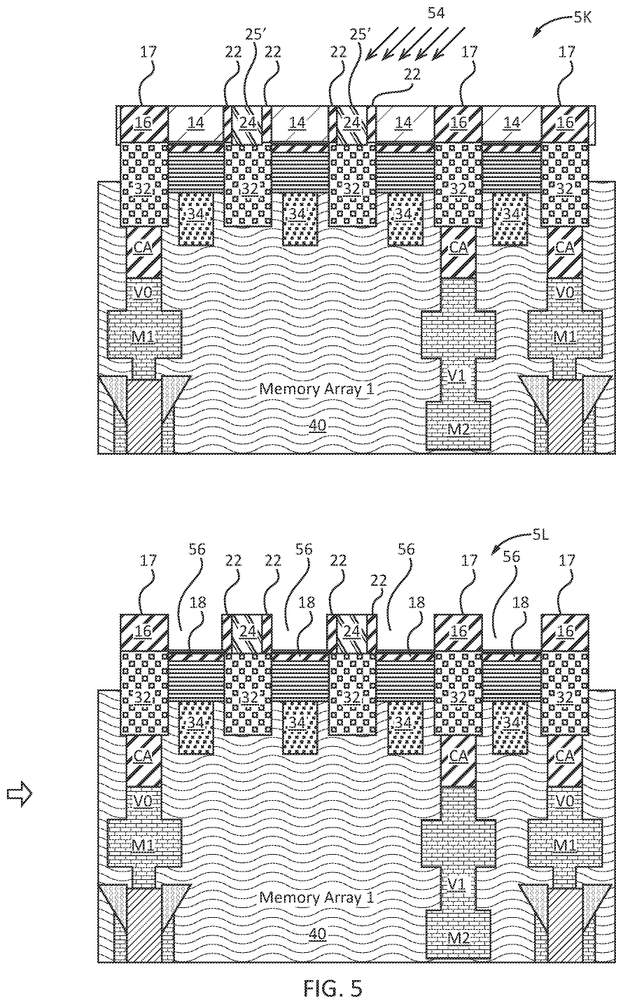

FIG. 5 is a cross-sectional view of the semiconductor structure of FIG. 4 where silicon (Si) and oxide removal is performed, in accordance with an embodiment of the present invention.

In various example embodiments, in structure 5K, silicon (Si) and oxide removal is performed by, an reactive ion etch (FIE) 54. In particular, the substrate 10 is removed and the dielectric layer 12 is removed such that top surfaces 17 of the STI regions 16 are exposed and such that top surfaces 25′ of the contacts 24 are exposed. The top surfaces of the dielectric liners and the top surfaces of portions of the SOI layer 14 are also exposed.

In structure 5L, the portions of the SOI layer 14 are removed to create openings 56 exposing the portions of the oxide layer 18. The sidewalls of the dielectric liners 22 are fully exposed, as are the sidewalls of the STI regions 16.

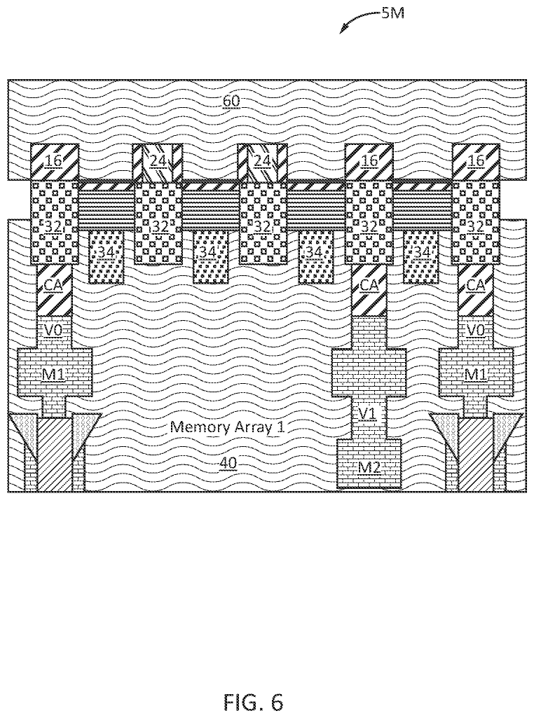

FIG. 6 is a cross-sectional view of the semiconductor structure of FIG. 5 where a dielectric is deposited over the contacts and the nanosheet stacks, in accordance with an embodiment of the present invention.

In various example embodiments, in structure SM, an interlayer dielectric (ILD) 60 is deposited over the contacts 24 and the nanosheet stacks 30, The IUD 60 directly contacts a top surface of the contacts 24. The ILD 60 directly contacts a top surface and sidewalls of the STI regions 16.

The ILD 60 can be any suitable material, such as, for example, porous silicates, carbon doped oxides, silicon dioxides, silicon nitrides, silicon oxynitrides, or other dielectric materials. Any known manner of forming the ILD 60 can be utilized. The ILD 60 can be formed using, for example, CVD, PECVD, ALD, flowable CVD, spin-on dielectrics, or PVD.

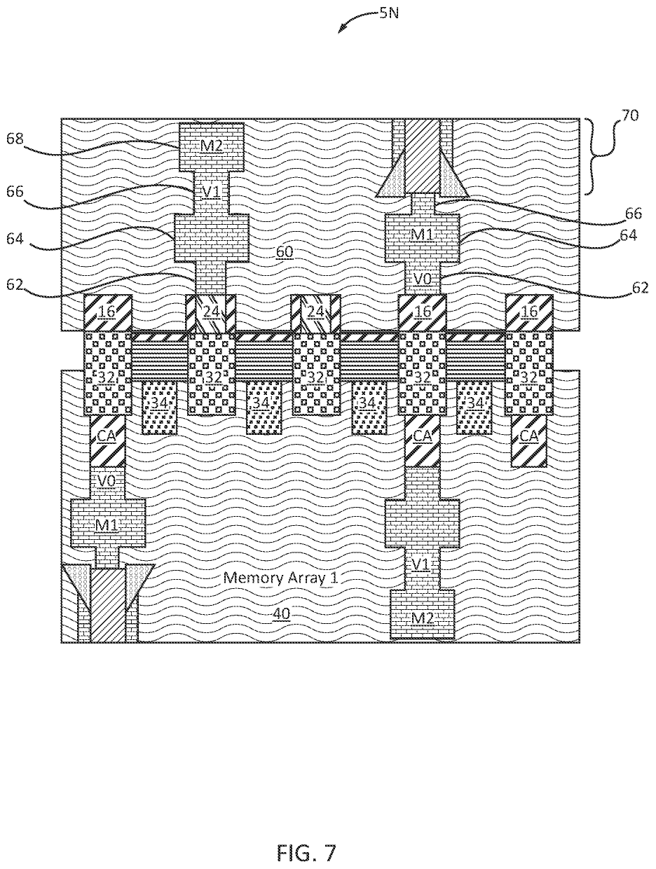

FIG. 7 is a cross-sectional view of the semiconductor structure of FIG. 6 where MOL, BEOL, and a second memory array are formed, in accordance with an embodiment of the present invention.

In various example embodiments, in structure SN, MOL, BEOL, and a second memory array are formed.

For example, on the left-hand side, a via (VO) 62 is formed over the contact 24, an M1 layer 64 is formed over the via 62, a via (V1) 66 is formed over the M1 layer 64, and an M2 layer 68 is formed over the via 66. All these components are positioned within the 60. Moreover, on the right-hand side, a via (VO) 62 is formed over the ST′ region 16, an M1 layer 64 is formed over the via 62, a via (V1) 66 is formed over the M1 layer 64, and an MTJ structure 70 is formed over the via 66, All these components are positioned within the dielectric layer 60. All these components collectively define the second memory array.

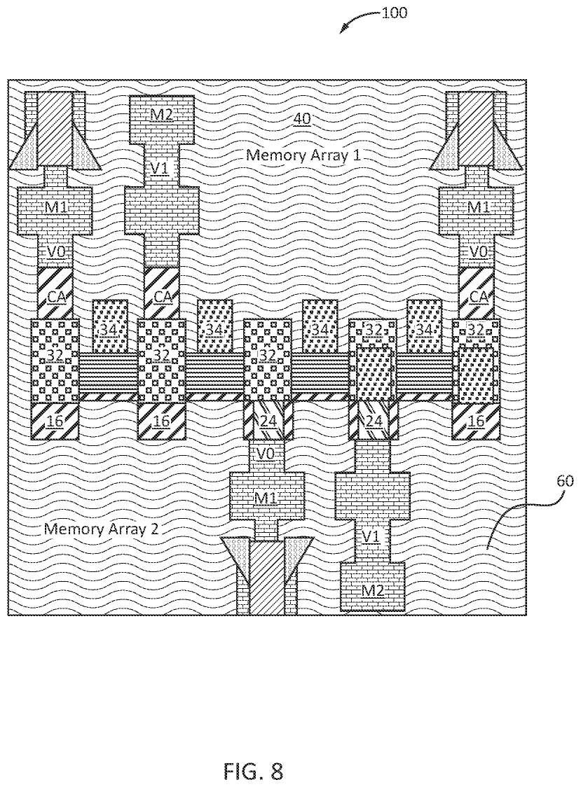

FIG. 8 is a cross-sectional view of the semiconductor structure of FIG. 7 where the wafer is flipped such that the first memory array is on the top and the second memory array is on the bottom, in accordance with an embodiment of the present invention.

In various example embodiments, in structure 100, the wafer is flipped such that the first memory array is on the top and the second memory array is on the bottom. As a result, the structure 100 includes a first memory array and a second memory array directly connected to the first memory array by nanosheet stacks and backside contacts. The first and second memory arrays collectively define a double-sided memory array on a complementary metal oxide semiconductor (CMOS) wafer. The first memory array is a first type of memory device and the second memory array is a second type of memory device different than the first memory device. It is further noted that the backside contacts can be through silicon vi as (TSV). Moreover, the nanosheet stacks physically separate the first memory array from the second memory array. Also, S/D contacts in the first memory array are vertically offset from S/L) contacts in the second memory array. The S/D contacts in the first memory array and the S/D contacts in the second memory array are vertically offset from the nanosheet stacks. Additionally, top surfaces of the nanosheet stacks directly contact gate contacts extending into the first memory array and bottom surfaces of the nanosheet stacks directly contact oxide layers placed adjacent the second memory array.

In conclusion, the exemplary embodiments of the present invention present a double-sided embedded memory array. The exemplary embodiments of the present invention introduce a structure of forming an embedded memory device where the structure is a wafer-level double-sided memory array on CMOS wafers. The memory arrays at both sides can be connected through nanosheets and back side contacts, TSV for example. The memory arrays at both sides can be different types of memory devices. In this structure, the memory density is increased, without pitch reduction, which will provide more manufacturability. Further, the exemplary embodiments of the present invention introduce a method of forming embedded memory devices where, after a typical front side memory array process, a temporary carrier is used to carry and flip the wafer to fabricate the back side memory array. The back side embedded memory array is fabricated by conventional BEOL interconnect processes. The back side contacts are fabricated first before front side front-end-of-line (FEOL) and can be used as alignment marks for the beginning of the back side process. Stated differently, the method includes forming a first set of SID contacts within a silicon on insulator (SOI) layer of a wafer, forming nanosheet stacks over portions of the SOI layer, constructing a first memory array, flipping the wafer, removing the portions of the SOI layer, constructing a second memory array, and re-flipping the wafer so that the second memory array is integrated with the first memory array by at least the nanosheet stacks to define a single complementary metal oxide semiconductor (CMOS) chip.

Regarding FIGS. 1-8, deposition is any process that grows, coats, or otherwise transfers a material onto the wafer. Available technologies include, but are not limited to, thermal oxidation, physical vapor deposition (PVD), chemical vapor deposition (CVD), electrochemical deposition (ECD), molecular beam epitaxy (MBE) and more recently, atomic layer deposition (ALD) among others. As used herein, “depositing” can include any now known or later developed techniques appropriate for the material to be deposited including but not limited to, for example: chemical vapor deposition (CVD), low-pressure CAI) (LPCVD), plasma-enhanced CVD (PECVD), semi-atmosphere CVD (SACVD) and high density plasma CVD (HDPCVD), rapid thermal CVD (RTCVD), ultra-high vacuum CVD (MOCVD), limited reaction processing CND (LRPCVD), metal-organic CVD (MOCVD), sputtering deposition, ion beam deposition, electron beam deposition, laser assisted deposition, thermal oxidation, thermal nitridation, spin-on methods, physical vapor deposition (PVD), atomic layer deposition (ALD), chemical oxidation, molecular beam epitaxy (MBE), plating, evaporation.

The term “processing” as used herein includes deposition of material or photoresist, patterning, exposure, development, etching, cleaning, stripping, implanting, doping, stressing, layering, and/or removal of the material or photoresist as needed in forming a described structure.

Removal is any process that removes material from the wafer: examples include etch processes (either wet or dry), and chemical-mechanical planarization (CMP), etc.

Patterning is the shaping or altering of deposited materials, and is generally referred to as lithography. For example, in conventional lithography, the wafer is coated with a chemical called a photoresist; then, a machine called a stepper focuses, aligns, and moves a mask, exposing select portions of the wafer below to short wavelength light; the exposed regions are washed away by a developer solution. After etching or other processing, the remaining photoresist is removed. Patterning also includes electron-beam lithography.

It is to be understood that the present invention will be described in terms of a given illustrative architecture; however, other architectures, structures, substrate materials and process features and steps/blocks can be varied within the scope of the present invention.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly, connected” or “directly coupled” to another element, there are no intervening elements present.

The present embodiments can include a design for an integrated circuit chip, which can be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical mechanisms (e.g., by providing a copy of the storage medium storing the design) or electronically (e.g., through the Internet) to such entities, directly or indirectly. The stored design is then converted into the appropriate format (e.g., CIDSII) for the fabrication of photolithographic masks, which usually include multiple copies of the chip design in question that are to be formed on a wafer. The photolithographic masks are utilized to define areas of the wafer and/or the layers thereon) to be etched or otherwise processed.

Methods as described herein can be used in the fabrication of integrated circuit chips. The resulting integrated circuit chips can be distributed by the fabricator in raw water form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ, where x is less than or equal to 1, etc. In addition, other elements can be included in the compound and still function in accordance with the present embodiments. The compounds with additional elements will be referred to herein as alloys.

Reference in the specification to “one embodiment” or “an embodiment” of the present invention, as well as other variations thereof, means that a particular feature, structure, characteristic, and so forth described in connection with the embodiment is included in at least one embodiment of the present invention. Thus, the appearances of the phrase “in one embodiment” or “in an embodiment”, as well any other variations, appearing in various places throughout the specification are not necessarily all referring to the same embodiment.

It is to be appreciated that the use of any of the following “I”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” and the like, can be used herein for ease of description to describe one element's or feature's relationship to another element(s) or feature(s) as illustrated in the FIGS. 1t will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

Having described preferred embodiments of methods and structures providing for constructing a double-sided embedded memory array (which are intended to be illustrative and not limiting), it is noted that modifications and variations can be made by persons skilled in the art in light of the above teachings. It is therefore to be understood that changes may be made in the particular embodiments described which are within the scope of the invention as outlined by the appended claims. Having thus described aspects of the invention, with the details and particularity required by the patent laws, what is claimed and desired protected by Letters Patent is set forth in the appended claims.

1. A semiconductor structure comprising:
a first memory array; and
a second memory array directly connected to the first memory array by nanosheet stacks and backside contacts.

2. The semiconductor structure of claim 1, wherein the first and second memory arrays collectively define a double-sided memory array on a complementary metal oxide semiconductor (CMOS) wafer.

3. The semiconductor structure of claim 1, wherein the first memory array is a first type of memory device and the second memory array is a second type of memory device different than the first type of memory device.

4. The semiconductor structure of claim 1, wherein the backside contacts are through silicon vias (TSV).

5. The semiconductor structure of claim 1, wherein the nanosheet stacks separate the first memory array from the second memory array.

6. The semiconductor structure of claim 1, wherein the nanosheet stacks are separated from each other by source/drain (SID) regions.

7. The semiconductor structure of claim 1, wherein S/D contacts in the first memory array are vertically offset from S/D contacts in the second memory array.

8. The semiconductor structure of claim 7, wherein the S/D contacts in the first memory array and the S/D contacts in the second memory array are vertically offset from the nanosheet stacks.

9. The semiconductor structure of claim 1, wherein top surfaces of the nanosheet stacks directly contact gate contacts extending into the first memory array and bottom surfaces of the nanosheet stacks directly contact oxide layers placed adjacent the second memory array.

10. A semiconductor structure comprising:
a first memory array; and
a second memory array integrated with the first memory array by at least a plurality of nanosheet stacks to define a single complementary metal oxide semiconductor (CMOS) chip.

11. The semiconductor structure of claim 10, wherein the first and second memory arrays are further integrated by a plurality of backside contacts.

12. The semiconductor structure of claim 11, wherein the backside contacts are through silicon vias (NV).

13. The semiconductor structure of claim 10, wherein the first memory array is a first type of memory device and the second memory array is a second type of memory device different than the first type of memory device.

14. The semiconductor structure of claim 10, wherein the nanosheet stacks separate the first memory array from the second memory array.

15. The semiconductor structure of claim 10, wherein the nanosheet stacks are separated from each other by source/drain (SID) regions.

16. The semiconductor structure of claim 10, wherein S/D contacts in the first memory array are vertically offset from S/D contacts in the second memory array.

17. The semiconductor structure of claim 16, wherein the S/D contacts in the first memory array and the S/D contacts in the second memory array are vertically offset from the nanosheet stacks.

18. The semiconductor structure of claim 10, wherein top surfaces of the nanosheet stacks directly contact gate contacts extending into the first memory array and bottom surfaces of the nanosheet stacks directly contact oxide layers placed adjacent the second memory array.

19. A method comprising:
forming a first set of S/11) contacts within a silicon on insulator (SOI) layer of a wafer;
forming nanosheet stacks over portions of the SOI layer;
constructing a first memory array;
flipping the wafer;
removing the portions of the SOI layer;
constructing a second memory array; and
re-flipping the water so that the second memory array is integrated with the first memory array by at least the nanosheet stacks to define a single complementary metal oxide semiconductor (CMOS) chip.

20. The method of claim 19, wherein the nanosheet stacks separate the first memory array from the second memory array.
